(19) United States
(12) Patent Application Publication
(10) Pub. No.: US 2026/0341675 A1
(43) Pub. Date: Oct. 29, 2026

(54) PROCESS FOR COMPACT DEPOSITION OF LITHIUM ON AN ELECTRICALLY CONDUCTIVE SUBSTRATE

(71) Applicant: ALBEMARLE GERMANY GmbH, Frankfurt a. M. (DE)

(72) Inventors: Ulrich WIETELMANN, Friedrichsdorf (DE); Dirk DAWIDOWSKI, Friedberg (DE)

(21) Appl. No.: 19/103,585

(22) PCT Filed: Jul. 24, 2023
(86) PCT No.: PCT/EP2023/070430

§ 371 Date: Feb. 13, 2025

(30) Foreign Application Priority Data
Aug. 23, 2022 (DE) 10 2022 121 255.6

(51) Int. Cl. H01M 4/1395; H01M 4/04; H01M 4/38; H01M 4/66

(52) U.S. Cl. CPC H01M 4/1395; H01M 4/0404; H01M 4/382; H01M 4/661

(57) ABSTRACT

A conductive substrate coated with compact lithium is described, wherein the substrate consists of sheet-like metals or sheet-like carbon-based materials, wherein on at least one side of the substrate a 1 to 5000 nm thick lithiophilic interlayer is present which contains or consists of at least one metallic or metalloid element selected from the group Zn, Al, B, Cd, Au, Ag, Si, Pb, Sn, Ge, Ga, In, Mg, Cr, V, Mo, W, Zr, Mn. Also described are processes for producing such a substrate coated with lithium.

The invention relates to processes for the production of a lithiophilic intermediate layer on an electrically conductive substrate and for the subsequent deposition of compact lithium on such an intermediate layer. Such lithiophilic coated substrates can therefore be used as a basic structure for the deposition of a compact lithium layer on this intermediate layer in the course of a contacting with a liquid lithium source of the composition Li(NH₃)₄₊ₓ (x=0-10). The invention further relates to the correspondingly manufactured substrates coated with the lithiophilic intermediate layer and the compact lithium.

### STATE OF THE ART

The currently commercially available lithium batteries function according to the intercalation principle. A graphitic material with a maximum capacity of 372 mAh/g (corresponding to the formula LiC₆) is used as the anode. Higher capacities and thus energy densities can be achieved by partial or complete replacement of graphite by alloy active materials (for example silicon or tin (“alloy anode materials”) or by complete replacement of graphitic materials by metallic lithium.

For the production of the thin lithium electrodes with lithium thicknesses <30 μm required for future lithium metal accumulators, the usual extrusion processes are not applicable. Alternatively, unfavorable, since cost-intensive processes such as a combination of extrusion and high-precision rolling, PVD techniques (plasma vapor deposition), or processes operating at higher temperatures (e.g. lithium melt deposition on current collectors at >180 °C) must be resorted to.

Therefore, simplified, low temperature and easily scalable processes for the production of thin lithium foils or lithium coatings are needed.

Solutions of alkali metals, especially metallic lithium in liquid ammonia, have long been known (e.g., W.C. Johnson, M. M. Piskur, J. Phys. Chem. 37 (1933) 93-99). When saturated lithium solutions are cooled to <−60 °C, phase separation occurs and a metallic, bronze-colored liquid layer of composition (Li(NH₃)₄, called Li bronze, forms over a dilute blue solution (H. Jaffe, Z. Phys. 93, 1935, 741-761). The lithium/ammonia system is described in detail in R. Hoffmann et al., Angew. Chem. Int. Ed. 2009, 48, 8198-8232. These liquids have a metal-like high electrical conductivity due to the presence of free electrons and they thus belong to the group of electrides.

J. Bronn (“Liquefied ammonia as a solvent”, Dec. 31, 1905, Julius Springer, Berlin, ISBN 978-3-642-50511-9, DOI: 10.1087/978-3-642-50821-9, pp. 116-117) describes that the ammonia can be removed from “lithium ammonium” under vacuum conditions at +50 to +60 °C, producing crystallized lithium metal.

GB 642 034 A Describes an electrochemical manufacturing process of alkali and alkaline earth metals. In this process, lithium salts are electrolyzed in liquid ammonia, among other things, and liquid or paste-like lithium/ammonia adducts are obtained. In a second step, lithium metal can be obtained from this by evaporating the ammonia at low temperatures. The metal is obtained in the form of a sponge-like mass (p. 7, lines 35-47).

WO 2021/245196 A1 describes processes for the production of lithium metal and lithium alloy shaped bodies from ammoniacal lithium metal solutions. In this process, solutions of metallic lithium in ammonia with the composition Li(NH₃)₄₊ₓ and x=0-10 are brought into contact with metallic or electronically conductive deposition substrates and the ammonia is removed at temperatures of −100 to 100 °C by overflowing with inert gas or at pressures of 0.001 to 700 mbar, so that the remaining lithium is deposited on the deposition substrate or/and it is doped with lithium or alloyed by it.

### OBJECT

The present invention aims to provide a scalable process for producing a thin, uniform and compact lithium coating on substrates with good electronic conductivity, such as metal or carbon-based films, which can also be carried out at mild temperatures. Further, such a substrate shall be provided, which is equipped with a thin, uniform and compact lithium coating.

### DESCRIPTION OF THE INVENTION

The lithium-coated substrates according to the invention are produced by contacting liquid lithium/ammonia compositions having the composition Li(NH₃)₄₊ₓ and x=0 -10 with electronically conductive substrates such as metal-or carbon-based foils, wherein the metal-or carbon-based substrates to be coated with lithium, usually foils, are in lithiophilized form, i.e. easily wettable with elemental lithium, by applying a metal-containing intermediate layer.

The lithiophilic interlayer consists of a 1-5000 nm, preferably 5-1000 nm thick coating of the metal-or carbon-based substrates/foils with at least one metallic or metalloid element capable of forming alloys with lithium. This element is selected from the group Zn, Al, B, Cd, Au, Ag, Si, Pb, Sn, Ge, Ga, In, Mg, Cr, V, Mo, W, Zr, Mn. Preferred elements are Zn, Al, B, Cd, Au, Ag, Si, Pb, Sn, Ga, In and Mg. The elements Zn, Al, Au, Si, Sn, Ga and are particularly preferred. These elements are present either in pure form or as a mixture of at least two of the elements mentioned. The lithiophilic coating is applied to at least one of the substrate/foil sides, preferably on all sides or both sides.

The compact lithium-coated conductive substrate according to the invention consists of sheet-like metal or sheet-like carbon-based material having on at least one side of the substrate a 1 to 5000 nm thick lithiophilic intermediate layer containing or consisting of at least one metallic or metalloid element selected from the group consisting of Zn, Al, B, Cd, Au, Ag, Si, Pb, Sn, Ge, Ga, In, Mg, Cr, V, Mo, W, Zr, Mn.

The process according to the invention for the deposition of compact lithium from a liquid lithium/ammonia composition with the composition Li(NH₃)₄₊ₓ, where x=0-10, on an electrically conductive substrate consisting of sheet-like metals or sheet-like carbon-based materials, is characterized in that the electrically conductive substrate is coated lithiophilizing on at least one side with an intermediate layer 1-5000 nm thick containing at least one element selected from the group Zn, Al, B, Cd, Au, Ag, Si, Pb, Sn, Ge, Ga, In, Mg, Cr, V, Mo, W, Zr, Mn, or consisting of at least one such element, and this construct is brought into contact with a lithium/ammonia composition of the composition Li(NH₃)₄₊ₓ, where x=0-10, and the ammonia is subsequently completely removed.

According to the invention, the lithiophilic interlayer can be deposited by different processes, the most important ones being the following:
1. physical vapor deposition (PVD). In this process, the substrate (e.g. a foil) is sputtered in a vacuum with at least one of the lithium-alloyable elements. When gold is used to build up an intermediate layer, the electrically conductive substrate is preferably coated beforehand with a thin (1-50 nm thick) nickel layer, provided the substrate itself is not made of nickel. The nickel layer serves as a diffusion barrier between the substrate and the gold layer.
2. electrochemical thin-film deposition (“plating”). In this galvanic process, a solution of the lithium-alloyable element is electrolyzed, with the electrically conductive substrate, usually in foil form, serving as the cathode on which the lithium-alloyable element is deposited. Prior to the subsequent lithium coating step according to the invention, electrolyte residues must be removed by dripping, washing and, if necessary, drying.
3. mechanical application of a thin foil containing the desired lithiophilizing metal. This process is particularly applicable for gold, since gold foils with very low layer thickness, i.e. <1 μm, are commercially available (for example from Nanjing Gold Foil Factory). In this case, an improved area-wide contacting and adhesion of the two layers/foils can be achieved by a suitable mechanical post-treatment process, e.g. pressing, rolling, coiling or the like. In industrial applications, this is best achieved by an automated roll-to-roll process.

As substrates with good electronic conductivity, flat structures consisting of copper, nickel, iron or films consisting of or containing carbon nanotubes (CNT's) or graphene are preferably used. Such substrates are typically used as current-conducting films in lithium batteries.

According to the invention, the layer thicknesses are determined by means of the SEM method (SEM=Scanning Electron Microscopy). The measurements were made in accordance with DIN EN ISO 9220 (Metallic coatings—Measurement of coating thickness—Scanning electron microscope method). Very thin coating thicknesses (<100 nm) can also be measured using X-ray methods, especially the reflectivity technique (XRR). This technique is described by Miho Yasaka, The Rigaku Journal, 26 (2), 2010.

The substrate/foil coated homogeneously, i.e. over the entire area with the interlayer, is next contacted with a solution of pure metallic lithium in ammonia, preferably with pure liquid lithium bronze of the composition Li(NH₃)₄ at temperatures in the range of −40 to +40 °C, preferably in the range of −10 to +30 °C, even more preferably +15 to +30°C, especially preferably at ambient temperatures of +20 to +30 °C. For this purpose, the electrically conductive substrate/foil equipped with the lithiophilic intermediate layer is dipped into the liquid lithium/ammonia composition. This can be done, for example, piece by piece with the aid of tweezers or continuously by a roll-to-roll process. Depending on the desired lithium layer thickness, the temperature and the type of lithiophilic coating, the contact times range from 0.1 to 10,000 seconds, preferably 1 to 2,000 seconds. During this process, part of the ammonia is evaporated and either an alloy consisting of lithium and the alloy-forming element of the intermediate layer is formed in the contact area with the conductive lithiophilic substrate or/and the metallic lithium is deposited in pure form over the intermediate layer. Lithium alloy layers are often formed with a decreasing concentration of the alloy-forming element towards the outside.

Lithium formation and deposition onto the electrically conductive substrates/foils equipped with a lithiophilic interlayer is then completed by quantitative removal of the ammonia. This step is carried out at temperatures between −40 °C and +100 °C, preferably −10 and +60 °C, more preferably +15 to +30 °C and particularly preferably at ambient temperatures of +20 to +30 °C, preferably under reduced pressure, i.e. in the pressure range of 0.001 to 700 mbar. Alternatively, the ammonia can also be removed by passing an inert gas stream. Since the ammonia concentration is reduced by the stripping gas (the inert gas stream) and the recovery of ammonia is made more difficult, this process is generally less cost-effective than the vacuum process. After complete removal of the ammonia, the elemental lithium metal remains in the form of a thin, homogeneous (cohesive), areal, compact layer on the lithiophilized deposition substrate.

With the process according to the invention, the metallic lithium is deposited on the lithiophilic intermediate layer with a layer thickness of 0.01 to 50 μm, preferably 0.1 to 30 μm, particularly preferably 0.5 to 25 μm, as determined by SEM.

Surprisingly, it was found that under these conditions, pure metallic lithium is deposited in a thin, homogeneous (coherent) compact form over the entire area on surfaces lithiophilized according to the invention. The compactness of the lithium can be characterized by measuring the specific surface area of the lithium coating, measured by gas adsorption using the BET (Brunauer, Emmett, Teller) method. These measurements were performed with the ASAP 2020 instrument from Micromeritics. Because of the high reactivity of metallic lithium, a noble gas such as argon/liquid argon was used as the determination gas. The measurements were carried out in accordance with ISO 9277 (“Determination of the specific surface area of solids by gas adsorption—BET”). The lithium layers produced by the method according to the invention have specific surface areas in the range between 500 and 20,000 cm²/g Li, preferably 1,000 to 10,000 cm²/g.

Commercially available technical lithium metal or preferably lithium of purer battery or alloy grade is used as the lithium source. Such metal grades are available, for example, from Sigma-Aldrich-Fluka (SAF). For example, there is a 99% “high sodium” technical grade with metal impurities of no more than 15,000 ppm, with sodium taking by far the highest percentage. Transition metals (especially Fe, Ag, Cu, Zn), on the other hand, are only present in the low ppm range (1-20 ppm). The sum of transition metal impurities is mostly in the range of 100 ppm and below. Furthermore, lithium is available from SAF in battery quality, i.e. a Li content (based on metallic trace elements) of 99.9 %. Such particularly pure battery grade contains a maximum of 1500 ppm of foreign metal impurities, with sodium predominating in this case as well.

For the process according to the invention, metallic lithium with a summed transition metal impurity content of not more than 200 ppm, particularly preferably not more than 100 ppm and very especially preferably not more than 50 ppm is preferably used. Impurities with main group metals, in particular metals of the alkali and alkaline earth metals and of the boron and carbon groups (13th and 14th groups), on the other hand, do not in principle interfere with the process. They can therefore also be present in larger contents, i.e. up to the percentage range.

The thermal decomposition or dissociation of the lithium ammonia solutions and compounds used, in particular of the defined lithium bronze, can take place either in the presence of an additional organic solvent (for example a hydrocarbon or ethers or amines) or without such additives. In particular, saturated aliphatic hydrocarbons such as pentanes, hexanes, heptanes, octanes or common, commercially available mixtures of such compounds (technical “petroleum ethers”, “white oils”, “benzines”) are suitable as organic solvents. Aromatic hydrocarbons can be used to a limited extent. The latter can promote undesirable decomposition with lithium amide formation. The use of etheric compounds such as diethyl ether, dibutyl ether, methyl tert-butyl ether, tetrahydrofuran, methyl tetrahydrofuran, tetrahydropyran, glymes and the like is also possible, but less preferred than the use of hydrocarbons.

Due to the high reactivity of metallic lithium and the Li/(NH₃) mixtures, all process steps of the lithium coating operation are carried out either under inert gas atmosphere (preferably argon, helium), a pure ammonia atmosphere or under vacuum conditions.

The metallic lithium freshly deposited from lithium-NH₃ compositions is very reactive to air and moisture. To ensure its safe further processing in technical applications, for example in the construction of battery cells, passivation of the metal surface, i.e. application of a thin protective layer, further preferred process step. Such a process step involves contacting with gaseous or liquid substances that form stable polymers and/or salts upon contact with lithium. Such a process step is described, for example, in WO 2011/073324A1.

In particular, elements or compounds selected from the group consisting of inorganic compounds consisting of: N₂, CO₂, CO, O₂, N₂O, NO, NO₂, HF, F₂, PF₃, PF₅, BF₃, POF₃, H₃PO₄, or liquid organic compounds/solvents/solutions (coating agents) selected from the groups: carbonic acid esters; lithium chelatoborate solutions as solutions in organic solvents; organosulfur compounds; N-containing organic compounds; organic phosphorus-containing compounds; partially fluorinated hydrocarbons; silicon-containing organic compounds. The organic solvents mentioned are preferably selected from the group consisting of: oxygen-containing heterocycles, carbonic acid esters, nitriles, carboxylic acid esters or ketones; the organosulfur compounds are preferably selected from the group consisting of: sulfites, sulfones, sultones. As lithium chelatoborate, lithium bis(oxalato)borate (LiBOB) is preferably used.

### EXAMPLES

### Example 1: Application of An Ultrathin Gold Layer on A Copper Foil

An 8 μm thick copper foil from Landt Instruments with a diameter of 9 mm was coated on both sides with ultra-thin (80 nm) gold foil from Nanjing Gold Foil Factory, and the metal foils were bonded together without bubbles by pressing lightly with a soft stamp.

### Example 2: Deposition of A Lithium Metal Film on A Copper Sheet

A 12 μm thick copper sheet, 10×10 mm, coated on both sides with an 80 mm thick gold layer, was inserted into an Ar-filled glove box. There it was brought into contact with (immersed in) lithium bronze at ambient temperature (25 °C) for about 20 seconds. After this time, the sheet was transferred to an Ar-filled desiccator and the ammonia was completely removed at first 500 mbar, then full oil pump vacuum (0.01 mbar). After this treatment, the sheet appeared uniformly silvery. By SEM examination of a cross-section of the sheet, a lithium layer thickness of about 5 μm was determined.

The specific surface area of the lithium layer on the top surface determined by BET was 1,800 cm²/g.

### Example 3: Application of A Gold Layer Using A Sputtering Process

A 20 μm thick copper sheet with a width of 15 mm was sputtered with gold in a high vacuum sputter coater from Leica (model EM ACE600). Argon was used as the sputtering gas, and the sputtering time was 15 minutes.

A gold layer thickness of 60 nm was determined by high-resolution SEM examination of a cross-section of the foil.

### Example 4: Deposition of A Lithium Metal Film on An Au-Sputtered Copper Sheet

A 20 μm thick copper sheet, 15×10 mm, coated on one side with a 60 nm thick gold layer, prepared according to Example 3, was placed in an Ar-filled glove box at ambient temperature (25 °C) in contact with (immersed in) lithium bronze for about 100 seconds. After this time, the sheet was transferred to an Ar-filled desiccator and the ammonia was completely removed at first 500 mbar, then full oil pump vacuum (0.01 mbar). After this treatment, the sheet appeared uniformly silvery. By means of SEM examination, a lithium layer thickness of about 8 μm was determined.

The specific surface area of the lithium layer on the top surface determined by BET was 2,100 cm²/g.

1. A process for depositing compact lithium from a liquid lithium-ammonia composition having the composition Li(NH₃)₄₊ₓ, where x=0-10, on an electrically conductive substrate consisting of sheet-like metals or sheet-like carbon-based materials, characterized in that the electrically conductive substrate is coated on at least one side by applying an intermediate layer 1-5000 nm thick containing at least one metallic or metalloid element selected from the group consisting of Zn, Al, B, Cd, Au, Ag, Si, Pb, Sn, Ge, Ga, In, Mg, Cr, V, Mo, W, Zr, Mn, or consisting of at least one such element, and this construct is brought into contact with a lithium/ammonia composition of the composition Li(NH₃)₄₊ₓ, where x=0-10, and the ammonia is subsequently completely removed.

2. The process according to claim 1, characterized in that the lithiophilized, electrically conductive substrate is brought into contact with the lithium/ammonia composition of the composition Li(NH₃)₄₊ₓ with (x=0-10) at temperatures in the range from −40 to +40 °C, preferably in the range from −10 to +30 °C, even more preferably +15 to +30 °C, particularly preferably at ambient temperatures of +20 to +30 °C and for a period of 0.1 to 10,000 seconds, preferably 1 to 2,000 seconds.

3. The process according to one of claims 1 or 2, characterized in that the ammonia is removed at temperatures from −40 to +100 °C by overflowing with inert gas or in the same temperature range at reduced pressure in the range from 0.001 to 700 mbar, so that the lithium remaining is deposited homogeneously, areally and compactly on the deposition substrate.

4. The process according to any one of claims 1 to 3, characterized in that the ammonia is removed at temperatures of −20 to +80 °C.

5. The process according to any one of claims 1 to 4, characterized in that lithium bronze with the composition Li(NH₃)₄ is preferably used as the lithium/ammonia composition.

6. The process according to any one of claims 1 to 5, characterized in that the lithiophilic intermediate layer is deposited by a process selected from:
(a) PVD deposition,
b) electrochemical thin film deposition, or
c) mechanical deposition
on the substrate, wherein the intermediate layer comprises or consists of at least one metallic or metalloid element selected from the group consisting of Zn, Al, B, Cd, Au, Ag, Si, Pb, Sn, Ge, Ga, In, Mg, Cr, V, Mo, W, Zr, Mn, preferably Zn, Al, B, Cd, Au, Ag, Si, Pb, Sn, Ga, In and Mg, more preferably Zn, Al, Au, Si, Sn, Ga and In.

7. The process according to any one of claims 1 to 6, characterized in that the lithium coating consisting of the compact metallic lithium has a specific surface area of 500 to 20,000 cm²/g Li, preferably 1,000 to 10,000 cm²/g Li, determined by means of the BET method using noble gas.

8. The process according to claim 1 to 7, characterized in that the metallic lithium deposited on the lithiophilic intermediate layer has a layer thickness, determined by means of SEM, of 0.01 to 50 μm, preferably 0.1 to 30 μm, particularly preferably 0.5 to 25 μm.

9. The process according to claim 1 to 7, characterized in that planar structures consisting of copper, nickel, iron or foils consisting of or containing carbon nanotubes (CNTs) or graphene are used as the electrically conductive substrate.

10. The process according to claim 1 to 9, characterized in that a surface passivation of the lithium-coated or -alloyed electrically conductive substrates is carried out by contacting with gaseous or liquid coating agents selected from the group consisting of anorganic compounds selected from: N₂, CO₂, CO, O₂, N₂O, NO, NO₂, HF, F₂, PF₃, PF₅, BF₃, POF₃, H₃PO₄; or liquid organic coating agents selected from the groups: carbonic acid esters; lithium chelatoborate solutions as solutions in organic solvents; organosulfur compounds; N-containing organic compounds; organic phosphorus-containing compounds; partially fluorinated hydrocarbons; silicon-containing organic compounds.

11. The process according to claim 10, characterized in that the organic solvents are selected from the group consisting of oxygen-containing heterocycles, carbonic acid esters, nitriles, carboxylic acid esters or ketones and the organosulfur compounds are selected from the group consisting of sulfites, sulfones, sultones.

12. A conductive substrate coated with compact lithium, wherein the substrate consists of sheet metals or sheet carbon-based materials, characterized in that on at least one side of the substrate there is a 1 to 5000 nm thick lithiophilic intermediate layer containing or consisting of at least one metal or metalloid element selected from the group Zn, Al, B, Cd, Au, Ag, Si, Pb, Sn, Ge, Ga, In, Mg, Cr, V, Mo, W, Zr, Mn.

13. The substrate according to claim 12, characterized in that the metallic or metalloid element is selected from Zn, Al, B, Cd, Au, Ag, Si, Pb, Sn, Ga, In and Mg, more preferably Zn, Al, Au, Si, Sn, Ga and In.

14. The substrate according to claim 12 or 13, characterized in that the lithium coating of the compact metallic lithium has a specific surface area determined by the BET method using noble gas of 500 to 20,000 cm²/g Li, preferably 1,000 to 10,000 cm²/g Li.

15. The substrate according to any one of claims 12 to 14, characterized in that the metallic lithium deposited on the lithiophilic intermediate layer has a layer thickness, determined by means of SEM, of 0.01 to 50 μm, preferably 0.1 to 30 μm, particularly preferably 0.5 to 25 μm.
